(19) United States
(12) Patent Application Publication
(10) Pub. No.: US 2021/0320649 A1
(43) Pub. Date: Oct. 14, 2021

(54) METHOD OF DYNAMICALLY CONTROLLING MINIMUM DUTY CYCLE AND RELATED HALF-BRIDGE BOOTSTRAP CIRCUIT

(71) Applicant: LSC Ecosystem Corporation, Taoyuan City (TW)

(72) Inventors: Chang-Ming Wang, Taipei City (TW); Tsung-Tai Cheng, Taoyuan City (TW); Hsiao-Wu Wang, Hualien County (TW)

(21) Appl. No.: 17/222,984

(22) Filed: Apr. 5, 2021

Related U.S. Application Data
(60) Provisional application No. 63/008,823, filed on Apr. 12, 2020.

(30) Foreign Application Priority Data
Jan. 4, 2021 (TW) 110100008

(51) Int. Cl. H03K 3/017; H03K 17/687; H02P 29/00

(52) U.S. Cl. CPC H03K 3/017; H03K 17/6871; H03K 2217/0072; H03K 2217/0063; H02P 29/00

(57) ABSTRACT

A half-bridge bootstrap circuit includes a high-side switch, a low-side switch, and a boot capacitor. A dynamically controlled minimum duty cycle curve is adopted to guarantee the minimum turn-on time of the low-side switch so that the boot capacitor can be sufficiently charged for keeping the high-side switch in the turn-on state. Also, the value of the minimum duty cycle curve can be dynamically set according to different operational phases of a load, thereby increasing the maximum output power of the load.

### CROSS REFERENCE TO RELATED APPLICATIONS

This application claims priority of Taiwan Application No. 110100008 filed on 2021 Jan. 4 and U.S. Provisional Application No. 63/008,823 filed on 2020 Apr. 12.

### BACKGROUND OF THE INVENTION

### 1. Field of the Invention

The present invention is related to a method of dynamically controlling minimum duty cycle and related half-bridge bootstrap circuit, and more particularly, to a method of dynamically controlling minimum duty cycle and related half-bridge bootstrap circuit according to different operational phases of a load.

### 2. Description of the Prior Art

An electric motor is an electrical machine that converts electrical energy into mechanical energy. There are various types of motors, including direct-current (DC) motors, alternating-current (AC) motor and stepper motors. One simple and easy way to control the speed and energy consumption of a motor is to regulate the amount of current flowing through its terminals using a pulse width modulation (PWM) technique. As its name suggests, the PWM speed control works by driving the motor with a series of high-frequency “ON-OFF” pulses and varying the duty cycle, the fraction of time that the output voltage is “ON” compared to when it is “OFF”, of the pulses while keeping the frequency constant.

A half-bridge bootstrap circuit is normally used to drive a motor and includes a boot capacitor, a high-side switch, and a low-side switch. The high-side switch and the low-side switch are coupled between a bus voltage and a ground voltage in a totem pole configuration, wherein the coupling point of the high-side switch and the low-side switch serves as an output end. When the high-side switch is turned off and the low-side switch is turned on, the DC voltage may charge the boot capacitor. When the high-side switch is turned on and the low-side switch is turned off, the energy stored in the boot capacitor may keep the high-side switch turned on, thereby transmitting the bus voltage to the output end for providing an output voltage.

In order to ensure that sufficient charges are stored in the boot capacitor for keeping the high-side switch turned on, a minimum duty (MD) scheme is normally adopted for limiting the minimum turn-on time of the low-side switch. The prior art half-bridge bootstrap circuit controls the low-side switch according to a constant minimum duty cycle curve, which also limits the maximum power of the motor as the power of the motor increases. Therefore, there is a need for a half-bridge bootstrap circuit capable of dynamically controlling minimum duty cycle.

### SUMMARY OF THE INVENTION

The present invention provides a method of dynamically controlling minimum duty cycle. The method includes turning off a high-side switch and turning on a low-side switch during a charging period for allowing a DC voltage to charge a capacitor; turning on the high-side switch and turning off the low-side switch during a discharging period subsequent to the charging period for allowing energy stored in the capacitor to charge parasite capacitance of the high-side switch, thereby keeping the high-side switch turned on and allowing a bus voltage to be transmitted to an output end for driving a motor; adjusting a first turn-on time of the high-side switch during the discharging period according to a status of the output end; and limiting a second turn-on time of the low-side switch during the charging period according to a dynamically controlled minimum duty cycle curve. The value of the dynamically controlled minimum duty cycle curve is not larger than a maximum value when a rotational speed of the motor is not larger than a first rotational speed. The value of the dynamically controlled minimum duty cycle curve is equal to the maximum value when the rotational speed of the motor is equal to the first rotational speed. The value of the dynamically controlled minimum duty cycle curve is not larger than the maximum value when the rotational speed of the motor is greater than the first rotational speed.

The present invention also provides a half-bridge bootstrap circuit which dynamically controls minimum duty cycle. The half-bridge bootstrap circuit includes an output end for providing an output voltage to drive a motor, a high-side switch configured to selectively conduct a signal path between a bus voltage and the output end, a low-side switch configured to selectively conduct a signal path between the output end and a ground voltage, a capacitor having a first end selectively coupled to a DC voltage and a second end selectively coupled to the output end, and a control circuit. The control circuit is configured to turn off the high-side switch and turn on the low-side switch during a charging period for coupling the output end to the ground voltage and allowing the DC voltage to charge the capacitor; turn on the high-side switch and turn off the low-side switch during a discharging period subsequent to the charging period for coupling the output end to the bus voltage and allowing energy stored in the capacitor to charge parasite capacitance of the high-side switch, thereby keeping the high-side switch turned on; adjust a first turn-on time of the high-side switch during the discharging period according to a status of the output end; and limit a second turn-on time of the low-side switch during the charging period according to a dynamically controlled minimum duty cycle curve. A value of the dynamically controlled minimum duty cycle curve is not larger than a maximum value when a rotational speed of the motor is not larger than a first rotational speed. The value of the dynamically controlled minimum duty cycle curve is equal to the maximum value when the rotational speed of the motor is equal to the first rotational speed. The value of the dynamically controlled minimum duty cycle curve is not larger than the maximum value when the rotational speed of the motor is larger than a first rotational speed and smaller than a second rotational speed which is larger than the first rotational speed; and the value of the dynamically controlled minimum duty cycle curve is zero when the rotational speed of the motor is larger than the second rotational speed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a half-bridge bootstrap circuit capable of dynamically controlling minimum duty cycle according an embodiment of the present invention.

FIG. 2 is a signal diagram illustrating the operation of the control circuit in a half-bridge bootstrap circuit according an embodiment of the present invention.

FIG. 3 is a characteristic diagram illustrating the operation of a motor driven by a half-bridge bootstrap circuit according an embodiment of the present invention.

FIG. 4 is a diagram illustrating the operation of dynamically controlling minimum duty cycle in a half-bridge bootstrap circuit according an embodiment of the present invention.

### DETAILED DESCRIPTION

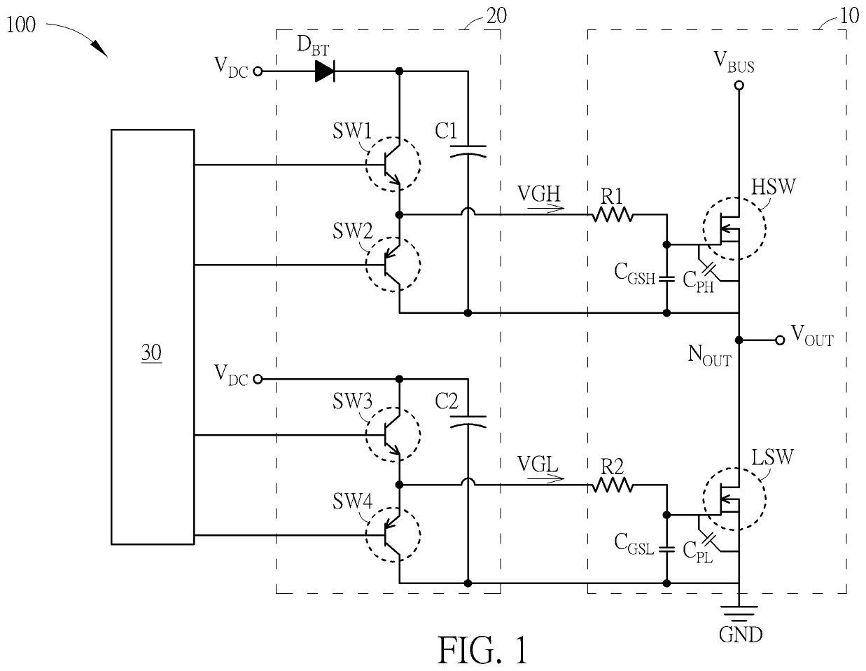

FIG. 1 is a diagram illustrating a half-bridge bootstrap circuit 100 capable of dynamically controlling minimum duty cycle according an embodiment of the present invention. The half-bridge bootstrap circuit 100 includes a power device 10, a driving output circuit 20, and a control circuit 30. The half-bridge bootstrap circuit 100 is configured to provide an output voltage V_{OUT} at an output end N_{OUT} for driving a load (not shown in FIG. 1).

The power device 10 includes a high-side switch HSW, a low-side switch LSW, resistors R1 and R2, and capacitors C_{GSH} and G_{GSL}. The high-side switch HSW includes a first end coupled to a bus voltage V_{BUS}, a second end coupled to the output end N_{OUT}, and a control end coupled to the driving output circuit 20 via the resistor R1 for receiving a control signal VGH. The low-side switch LSW includes a first end coupled to the output end N_{OUT}, a second end coupled to the ground voltage GND, and a control end coupled to the driving output circuit 20 via the resistor R2 for receiving a control signal VGL. C_{PH} represents the parasite capacitance between the control end and the second end of the high-side switch HSW, and C_{PL} represents the parasite capacitance between the control end and the second end of the low-side switch LSW. The capacitor C_{GSH} is coupled in parallel with the parasite capacitance C_{PH} of the high-side switch HSW, and configured to prevent the malfunction of the high-side switch HSW and adjust the switching speed of the high-side switch HSW. The capacitor C_{GSL} is coupled in parallel with the parasite capacitance C_{PL} of the low-side switch LSW, and configured to prevent the malfunction of the low-side switch LSW and adjust the switching speed of the low-side switch LSW.

The driving output circuit 20 includes switches SW1-SW4, capacitors C1-C2, and a boot diode D_{BT}. The boot diode D_{BT} includes an anode coupled to a DC voltage V_{Dc} and a cathode coupled to the output end N_{OUT} via the capacitor C1. The switch SW1 includes a first end coupled to cathode of the boot diode D_{BT}, a second end coupled to the resistor R1 of the power device 10, and a control end coupled to the control circuit 30. The switch SW2 includes a first end coupled to second end of the switch SW1, a second end coupled to the output end N_{OUT}, and a control end coupled to the control circuit 30. The switch SW3 includes a first end coupled to the DC voltage V_{DC}, a second end coupled to the resistor R2 of the power device 10, and a control end coupled to the control circuit 30. The switch SW4 includes a first end coupled to the second end of the switch SW3, a second end coupled to the ground voltage GND, and a control end coupled to the control circuit 30. The capacitor C1 is a boot capacitor and includes a first end coupled to the DC voltage V_{DC} via the boot diode D_{BT}, and a second end coupled to the output end N_{OUT}. The capacitor C2 includes a first end coupled to the DC voltage V_{DC} and a second end coupled to the ground voltage GND.

The control circuit is configured to control the operation of the switches SW1-SW4 according to the status of the output end N_{OUT} for providing the control signals VGH and VGL, thereby selectively turning on/off the high-side switch HSW and the low-side switch LSW so that the half-bridge bootstrap circuit 100 may alternatively operate in charging periods and discharging periods.

During each charging period of the half-bridge bootstrap circuit 100, the control circuit 30 is configured to control the switches SW1-SW4 of the driving output circuit 20 to output a control signal VGH having a disable level and a control signal VGL having an enable level, thereby turning off the high-side switch HSW and turning on the low-side switch LSW. Under such circumstance, the output end N_{OUT} may be coupled to the ground voltage GND via the turned-on switch SW2, and the DC voltage V_{DC} may charge the capacitor C1 via the forward-biased boot diode D_{BT}. In other words, the amount of energy stored in the capacitor C1 during each charging period is determined by the turn-on time of the low-side switch LSW.

During each discharging period of the half-bridge bootstrap circuit 100, the control circuit 30 is configured to control the switches SW1-SW4 of the driving output circuit 20 to output a control signal VGH having an enable level and a control signal VGL having a disable level, thereby turning on the high-side switch HSW and turning off the low-side switch LSW. Under such circumstance, the output end N_{OUT} may be coupled to the bus voltage V_{BUS} via the turned-on high-side switch HSW, and the reverse-biased boot diode D_{BT} is turned off. Meanwhile, the energy stored in the capacitor C1 during the charging period may charge the parasite capacitance C_{PH} of the high-side switch HSW, thereby keeping the high-side switch HSW turned on. Also, the bus voltage V_{BUS} may be transmitted to the output end N_{OUT} via the turned-on high-side switch HSW for providing the output voltage V_{OUT}. In other words, the value of the output voltage V_{OUT} is determined by the turn-on time of the high-side switch HSW during each discharging period.

Motors are normally driven using sinusoid waves. In motor driving applications, the half-bridge bootstrap circuit 100 of the present invention is configured to provide the output voltage V_{OUT} as sinusoidal wave having various frequencies and peaks so as to create magnetic field inside the motor, thereby controlling the rotational speed of the motor. As well-known to those skilled in the art, a motor can rotate in the forward direction or backward direction. The direction of motor rotation may be altered by changing the polarity of the input voltages, the phase sequence of the input voltages or the signal commands indifferent applications (such as for a DC motor, an AC motor or a stepper motor). For ease of explanation, a single direction of motor rotation is used to illustrate the present invention in subsequent paragraphs. The present invention can also be applied to the other direction of motor rotation similarly.

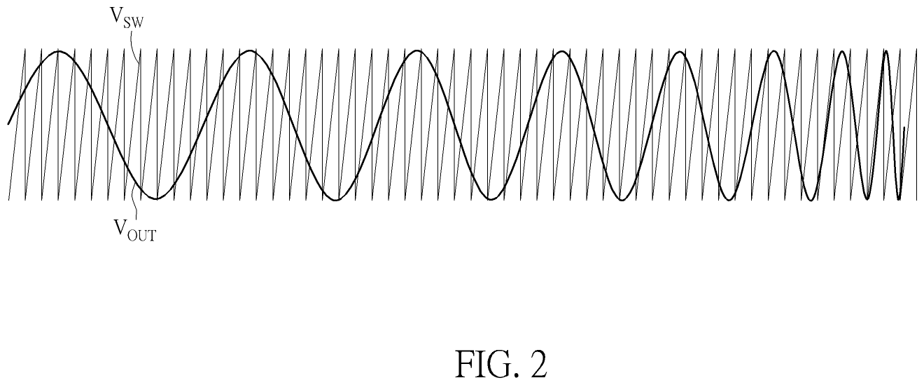

FIG. 2 is a signal diagram illustrating the operation of the control circuit 30 in the half-bridge bootstrap circuit 100 according an embodiment of the present invention. The control circuit 30 is configured to control the turn-on time and the turn-off time of the high-side switch HSW and the low-side switch LSW according to the frequency of the output voltage V_{OUT} and the frequency of a switching voltage V_{SW}. The switching voltage V_{SW} is a pulse signal having a constant frequency and a constant peak. The frequency and the peak of the output voltage V_{OUT} are associated with the output power of the half-bridge bootstrap circuit 100. In the application of motor driving, the frequency and the peak of the output voltage V_{OUT} are associated with the rotational speed of the motor. In order to ensure the integrity of the waveform of the output voltage V_{OUT}, the frequency of the switching voltage V_{SW} is usually larger than the frequency of the output voltage V_{OUT} by at least five times. For illustrative purpose in FIG. 2, the frequency of the output voltage V_{OUT} gradually increases, and the peaks of the switching voltage V_{SW} and the output voltage V_{OUT} have the same value.

When the level of the switching voltage V_{SW} is higher than the level of the output voltage V_{OUT}, the control circuit 30 is configured to control the driving output circuit 20 for turning off the high-side switch HSW and turning on the low-side switch LSW. When the level of the switching voltage V_{SW} is lower than the level of the output voltage V_{OUT}, the control circuit 30 is configured to control the driving output circuit 20 for turning on the high-side switch HSW and turning off the low-side switch LSW. As depicted in FIG. 2, a larger peak of the output voltage V_{OUT} results in a longer turn-on time of the high-side switch HSW, and a smaller peak of the output voltage V_{OUT} results in a shorter turn-on time of the high-side switch HSW. On the other hand, a lower frequency of the output voltage V_{OUT} results in a longer turn-on time and more frequent switching of the high-side switch HSW.

In order to ensure that sufficient charges are stored in the capacitor C1 during the discharging period for keeping the high-side switch HSW turned on, the control circuit 30 of the present invention is configured to limit the minimum turn-on time of the low-side switch LSW during the charging period according to a dynamically controlled minimum duty cycle curve, i.e., allowing sufficient charges to be stored in the capacitor C1 during the charging period. More specifically, if the control signal VGL is kept at the enable level for a period which is not smaller than the turn-on time of the dynamically controlled minimum duty cycle curve, a maximized power output may be provided.

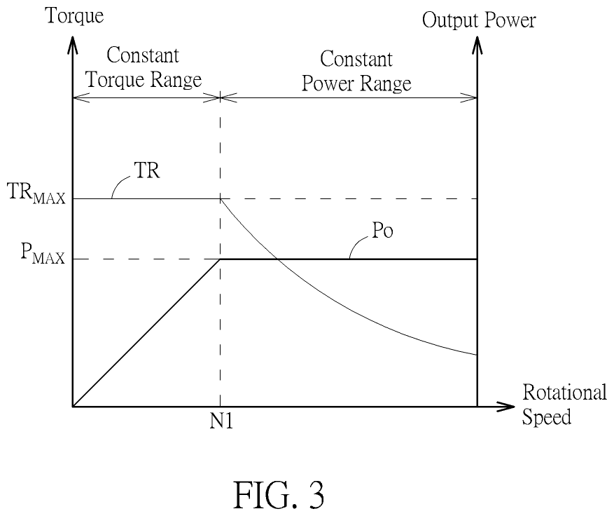

FIG. 3 is a characteristic diagram illustrating the operation of a motor driven by the half-bridge bootstrap circuit 100 according an embodiment of the present invention. The horizontal axis represents the rotational speed of the motor. The left-side vertical axis represents the torque of the motor. The right-side vertical axis represents the output power of the motor. TR represents the curve showing the relationship between the torque and the rotational speed of the motor. Po represents the curve showing the relationship between the output power and the torque of the motor, wherein the output power Po is substantially equal to a product of the torque and the rotational speed of the motor. The range before the rotational speed of the motor reaches a threshold rotational speed N1 is called the constant torque range. The range after the rotational speed of the motor reaches the threshold rotational speed N1 is called the constant power range. When the rotational speed of the motor is within the constant torque range, the torque TR of the motor is kept at a constant maximum torque TR_{MAX}. When the rotational speed of the motor is within the constant power range (after the rotational speed of the motor reaches the threshold rotational speed N1), the torque TR of the motor decreases as the rotational speed of the motor increases, and the output power Po of the motor is kept at a constant maximum output power PR_{MAX}. The value of the threshold rotational speed N1 is associated with the bus voltage V_{BUS}, wherein a larger bus voltage V_{BUS} results in a larger threshold rotational speed N1.

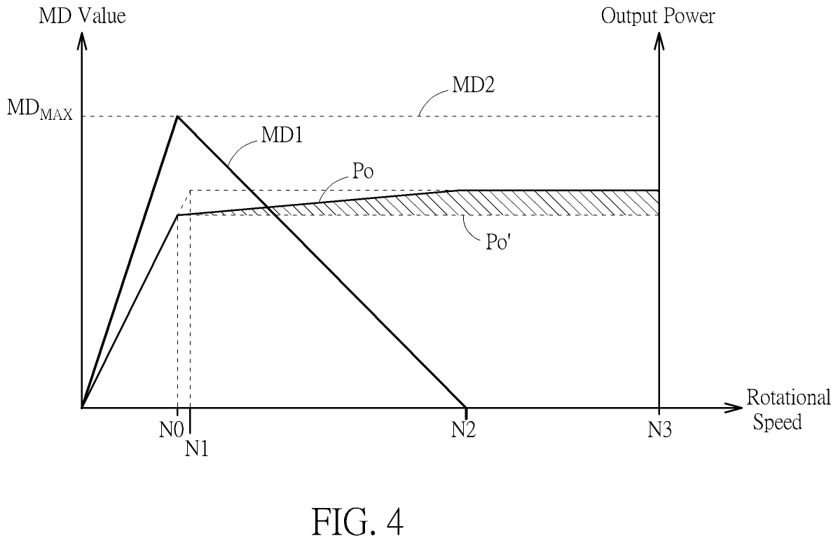

FIG. 4 is a diagram illustrating the operation of dynamically controlling minimum duty cycle in the half-bridge bootstrap circuit 100 according an embodiment of the present invention. The horizontal axis represents the rotational speed of the motor. The left-side vertical axis represents the MD values of the minimum duty cycle curves. The right-side vertical axis represents the output power of the motor. MD1 represents one embodiment of the dynamically controlled minimum duty cycle curve adopted by the half-bridge bootstrap circuit 100 of the present invention. MD2 represents a constant minimum duty cycle curve adopted by a prior art half-bridge bootstrap circuit. Po represents the curve showing the relationship between the output power and the torque of the motor driven by the half-bridge bootstrap circuit 100 of the present invention. Po′ represents the curve showing the relationship between the output power and the torque of the motor driven by the prior art half-bridge bootstrap circuit. As depicted in FIGS. 3 and 4, when the half-bridge bootstrap circuit 100 of the present invention is used to drive the motor, different operational phases of the motor require different MD values. Therefore, the control circuit 30 in the half-bridge bootstrap circuit 100 of the present invention is configured to adopt the dynamically controlled minimum duty cycle curve MD1 whose maximum value is equal to MD_{MAX}.

When the rotational speed of the motor is smaller than the threshold rotational speed N1, the output power of the motor has not reached the constant power range and the peak of the corresponding output voltage V_{OUT} is smaller than the peak of the switching signal W_{SW}, which allows the low-side switch LSW to have a longer turn-on time for the capacitor C1 to be sufficiently charged. Under such circumstance, the dynamically controlled minimum duty cycle curve MD1 may have any value smaller than the maximum value MD_{MAX}. When the rotational speed of the motor is between 0 and N0, the dynamically controlled minimum duty cycle curve MD1 has not been able to effectively limit the output power of the motor, and the output power Po of the motor increases with its rotational speed. When the rotational speed of the motor approaches the threshold rotational speed N1 and reaches N0, the dynamically controlled minimum duty cycle curve MD1 is able to effectively limit the output power Po of the motor so that the limitation of the constant power range is reached in advance, wherein the difference between N0 and N1 is determined by the setting of the dynamically controlled minimum duty cycle curve MD1. In the embodiment illustrated in FIG. 4, when the rotational speed of the motor is smaller than the threshold rotational speed N1, the value of the dynamically controlled minimum duty cycle curve MD1 increases in a linear manner as the rotational speed of the motor increases. In another embodiment when the rotational speed of the motor is smaller than the threshold rotational speed N1, the value of the dynamically controlled minimum duty cycle curve MD1 increases in a polynomial manner, an exponential manner or a stepwise manner as the rotational speed of the motor increases.

When the rotational speed of the motor reaches the threshold rotational speed N1, the output power Po of the motor reaches the limitation of the constant power range, and the peak of the corresponding output voltage V_{OUT} is substantially equal to the peak of the switching signal V_{SW}, which shortens the turn-on time of the low-side switch LSW. In order to ensure that sufficient charges are stored in the capacitor C1 during the shorter turn-on time of the low-side switch LSW for keeping the high-side switch HSW turned on during the subsequent period, the dynamically controlled minimum duty cycle curve MD1 is set to the maximum value MD_{MAX}. Since the value the threshold rotational speed N1 is associated with the value of the bus voltage V_{BUS}, the strictest condition with the minimum bus voltage V_{BUS} and the maximum output power is generally adopted for determining the value of the threshold rotational speed N1. The dynamically controlled minimum duty cycle curve MD1 may then be set to the maximum value M_{DMAX} in order to allow the low-side switch LSW to have sufficient turn-on time for the capacitor C1 to be sufficiently charged.

As previously stated, the levels and the frequencies of the output voltage V_{OUT} and the switching signal V_{SW} are determined by the rotational speed of the motor. When the rotational speed of the motor is between N1 and N2, the peaks of the output voltage V_{OUT} and the switching signal V_{SW} are the same. Under such circumstance, the frequency of the output voltage V_{OUT} increases, the required number of switching the low-side switch LSW decreases, and the value of the dynamically controlled minimum duty cycle curve MD1 may be set to decrease as the rotational speed of the motor increases. In the embodiment illustrated in FIG. 4, when the rotational speed of the motor is between N1 and N2, the value of the dynamically controlled minimum duty cycle curve MD1 decreases in a linear manner as the rotational speed of the motor increases. In another embodiment when the rotational speed of the motor is between N1 and N2, the value of the dynamically controlled minimum duty cycle curve MD1 decreases in a polynomial manner, an exponential manner or a stepwise manner as the rotational speed of the motor increases.

When the rotational speed of the motor is between 0 and N1 and between N1 and N2, the rising slope and the falling slope of the dynamically controlled minimum duty cycle curve MD1 maybe determined according to the value of the bus voltage V_{BUS}, the value of the capacitor C1, the characteristic of the high-side switch HSW, the characteristic of the low-side switch LSW, the leakage current of the driving output circuit 20, and/or the PWM switching method of the high-side switch HSW and the low-side switch LSW. Since the value of the bus voltage V_{BUS} is proportional to the threshold rotational speed N1, the dynamically controlled minimum duty cycle curve MD1 may be determined according to the values of the bus voltage V_{BUS} in different applications. Since the maximum storage of the capacitor C1 is associated with its location, the environmental temperature and the operation space, the dynamically controlled minimum duty cycle curve MD1 may be determined according to the storage of the capacitor C1. Since the parasite capacitance of the high-side/low-side switches is periodically charged and discharged during operation, the dynamically controlled minimum duty cycle curve MD1 may be determined according to the type of the high-side/low-side switches and the values of the corresponding parasite capacitance. Since the leakage current of the driving output circuit 20 depletes the energy stored in the capacitor C1, the dynamically controlled minimum duty cycle curve MD1 may be determined according to the leakage current of the driving output circuit 20. Since a larger number of switching times results in larger switching loss and different modulation methods result in different energy consumption at the signal peaks, the dynamically controlled minimum duty cycle curve MD1 may be determined according to the PWM switching method of the high-side switch HSW and the low-side switch LSW.

When the rotational speed of the motor reaches N2, the required number of switching times of the low-side switch LSW is small enough so that the energy stored in the capacitor C1 is sufficient to maintain the operation of the high-side switch HSW. Under such circumstance, the dynamically controlled minimum duty cycle curve MD1 may be set to zero.

As depicted in FIG. 4, the prior art half-bridge bootstrap circuit controls the low-side switch according to a constant minimum duty cycle curve MD2, which also limits the maximum power of the motor (as depicted by the curve Po′). In contrast, the half-bridge bootstrap circuit 100 of the present invention adopts the dynamically controlled minimum duty cycle curve MD1 whose value is determined according to different operational phases of the motor, thereby capable of increasing the maximum power of the motor (as depicted by the curve Po). The amount of increase in the output power may be represented by the striped region between the curve Po and the curve Po′ in FIG. 4.

In an embodiment of the present invention, each of the high-side switch HSW, the low-side switch LSW, and the switches SW1-SW4 may be a metal-oxide-semiconductor field-effect transistor (MOSFET), a bipolar junction transistors (BJT), or any other device having similar function. For N-type transistors, the enable level is logic 1, and the disable level is logic 0; for P-type transistors, the enable level is logic 0, and the disable level is logic 1. However, the types of the above-mentioned switches do not limit the scope of the present invention.

In conclusion, the half-bridge bootstrap circuit of the present invention adopts the dynamically controlled minimum duty cycle curve for limiting the minimum turn-on time of the low-side switch, thereby ensuring that sufficient charges are stored in the boot capacitor for keeping the high-side switch turned on. Meanwhile, the value of the dynamically controlled minimum duty cycle curve is determined according to different operational phases of the motor, thereby capable of increasing the maximum power of the motor for driving the load.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of dynamically controlling minimum duty cycle, comprising:
turning off a high-side switch and turning on a low-side switch during a charging period for allowing a direct-current (DC) voltage to charge a capacitor;
turning on the high-side switch and turning off the low-side switch during a discharging period subsequent to the charging period for allowing energy stored in the capacitor to charge parasite capacitance of the high-side switch, thereby keeping the high-side switch turned on and allowing a bus voltage to be transmitted to an output end for driving a motor;
adjusting a first turn-on time of the high-side switch during the discharging period according to a status of the output end; and
limiting a second turn-on time of the low-side switch during the charging period according to a dynamically controlled minimum duty cycle curve, wherein:
a value of the dynamically controlled minimum duty cycle curve is not larger than a maximum value when a rotational speed of the motor is not larger than a first rotational speed;
the value of the dynamically controlled minimum duty cycle curve is equal to the maximum value when the rotational speed of the motor is equal to the first rotational speed; and
the value of the dynamically controlled minimum duty cycle curve is not larger than the maximum value when the rotational speed of the motor is greater than the first rotational speed.

2. The method of claim 1, wherein the value of the dynamically controlled minimum duty cycle curve increases as the rotational speed of the motor increases when the rotational speed of the motor is not larger than the first rotational speed.

3. The method of claim 2, wherein the value of the dynamically controlled minimum duty cycle curve increases in a linear manner, a polynomial manner, an exponential manner or a stepwise manner as the rotational speed of the motor increases when the rotational speed of the motor is not larger than the first rotational speed.

4. The method of claim 2, further comprising:
determining a rising slope of the dynamically controlled minimum duty cycle curve when the rotational speed of the motor is not larger than the first rotational speed according to a value of the bus voltage, a value of the capacitor, a characteristic of the high-side switch, a characteristic of the low-side switch, a method of switching the high-side switch, and/or a method of switching the low-side switch.

5. The method of claim 1, wherein the value of the dynamically controlled minimum duty cycle curve decreases as the rotational speed of the motor increase when the rotational speed of the motor is larger than the first rotational speed.

6. The method of claim 5, wherein the value of the dynamically controlled minimum duty cycle curve decreases in a linear manner, a polynomial manner, an exponential manner or a stepwise manner as the rotational speed of the motor increases when the rotational speed of the motor is larger than the first rotational speed.

7. The method of claim 5, further comprising:
determining a falling slope of the dynamically controlled minimum duty cycle curve when the rotational speed of the motor is larger than the first rotational speed according to a value of the bus voltage, a value of the capacitor, a characteristic of the high-side switch, a characteristic of the low-side switch, a method of switching the high-side switch, and/or a method of switching the low-side switch.

8. The method of claim 1, further comprising:
the value of the dynamically controlled minimum duty cycle curve is zero when the rotational speed of the motor is larger than a second rotational speed which is larger than the first rotational speed.

9. The method of claim 1, further comprising:
providing a switching signal having a constant frequency and a constant peak, wherein the constant frequency of the switching signal is larger than a frequency of an output voltage established on the output end;
turning off the high-side switch and turning on the low-side switch when a level of the switching signal is higher than a level of the output voltage; and
turning on the high-side switch and turning off the low-side switch when the level of the switching signal is lower than the level of the output voltage.

10. The method of claim 1, wherein the second turn-on time of the low-side switch during the charging period is longer than or equal to a third turn-on time of the dynamically controlled minimum duty cycle curve.

11. A half-bridge bootstrap circuit which dynamically controls minimum duty cycle, comprising:
an output end for providing an output voltage to drive a motor;
a high-side switch configured to selectively conduct a signal path between a bus voltage and the output end;
a low-side switch configured to selectively conduct a signal path between the output end and a ground voltage;
a capacitor, including:
a first end selectively coupled to a direct-current (DC) voltage; and
a second end selectively coupled to the output end;
a control circuit configured to:
turn off the high-side switch and turn on the low-side switch during a charging period for coupling the output end to the ground voltage and allowing the DC voltage to charge the capacitor;
turn on the high-side switch and turn off the low-side switch during a discharging period subsequent to the charging period for coupling the output end to the bus voltage and allowing energy stored in the capacitor to charge parasite capacitance of the high-side switch, thereby keeping the high-side switch turned on;
adjust a first turn-on time of the high-side switch during the discharging period according to a status of the output end; and
limit a second turn-on time of the low-side switch during the charging period according to a dynamically controlled minimum duty cycle curve, wherein:
a value of the dynamically controlled minimum duty cycle curve is not larger than a maximum value when a rotational speed of the motor is not larger than a first rotational speed;
the value of the dynamically controlled minimum duty cycle curve is equal to the maximum value when the rotational speed of the motor is equal to the first rotational speed;
the value of the dynamically controlled minimum duty cycle curve is not larger than the maximum value when the rotational speed of the motor is larger than a first rotational speed and smaller than a second rotational speed which is larger than the first rotational speed; and
the value of the dynamically controlled minimum duty cycle curve is zero when the rotational speed of the motor is larger than the second rotational speed.

12. The half-bridge bootstrap circuit of claim 11, further comprising a boot diode having an anode coupled to the DC voltage and a cathode coupled to a first end of the capacitor, wherein:
the high-side switch includes:
a first end coupled to the bus voltage;
a second end coupled to the output end; and
a control end for receiving a first control signal; and
the low-side switch includes:
a first end coupled to the output end;
a second end coupled to the ground voltage; and
a control end for receiving a second control signal.

13. The half-bridge bootstrap circuit of claim 11, wherein the second turn-on time of the low-side switch during the charging period is longer than or equal to a third turn-on time of the dynamically controlled minimum duty cycle curve.
